(19) United States
(12) Patent Application Publication
(10) Pub. No.: US 2026/0052744 A1
(43) Pub. Date: Feb. 19, 2026

(54) GROUP III-OXIDE DEVICES WITH SELECT SEMI-INSULATING AREAS

(71) Applicant: Cornell University, Ithaca, NY (US)

(72) Inventors: Bennett Cromer, Ithaca, NY (US); Huili Grace Xing, Ithaca, NY (US); Debdeep Jena, Ithaca, NY (US); Daniel Dryden, Dayton, OH (US)

(73) Assignee: Cornell University, Ithaca, NY (US)

(21) Appl. No.: 19/101,537

(22) PCT Filed: Aug. 4, 2023
(86) PCT No.: PCT/US2023/029539

§ 371 Date: Feb. 5, 2025

Related U.S. Application Data
(60) Provisional application No. 63/395,809, filed on Aug. 6, 2022.

(51) Int. Cl. H10D 62/60; H10D 8/00; H10D 8/60; H10D 62/10; H10D 62/17; H10D 62/80; H10D 84/82

(52) U.S. Cl. CPC H10D 62/60; H10D 8/411; H10D 62/125; H10D 62/221; H10D 62/875; H10D 84/82; H10D 8/60

(57) ABSTRACT

Group III oxide semiconducting devices with effective device isolation and edge termination regions.

### CROSS-REFERENCE TO RELATED APPLICATIONS

This application claims priority to U.S. Provisional Patent Application No. 63/395809, filed Aug. 6, 2022, which is incorporated herein by reference in its entirety and for all purposes.

### STATEMENT REGARDING FEDERALLY SPONSORED RESEARCH OR DEVELOPMENT

This invention was made with U.S. Government support from the Air Force Office of Sponsored Research under contract No. E70-8618/8619. The U.S. Government has certain rights in the invention.

### BACKGROUND

These teachings relate generally to Group III oxide semiconductor devices with select semi-insulating areas.

Among future materials for high power electronic materials, Beta-phase gallium oxide (β-Ga2O3) has grown to be a promising candidate due to its high critical field, relatively low hardness, and low-cost melt-grown processing. These properties allow for gallium oxide to compete as a cost-effective replacement and upgrade for current Si, SiC, and GaN-based power electronics, while being compatible with existing Si-centered CMP processing. However, fundamental components such as selective semi-insulating definition have not been effectively demonstrated. Owing to an intrinsic material property, Ga₂O₃ can not utilize bipolar homojunctions for edge termination and device isolation utilized in many power devices.

Ga₂O₃ isolation scheme via Magnesium (Mg) doping, Nitrogen (N) doping, thermal oxidation, hetero p-n-junctions and mesa etching have been reported. However, these results have not demonstrated the thermal and frequency dependence of their respective scheme. Mesa etching also cannot change the conductivity of the gallium oxide, only remove material to create air barriers.

Thus, another scheme must be developed for effective device isolation and edge termination in Ga2O3.

There is a need for Group II oxide semiconducting devices with effective device isolation and edge termination regions.

### BRIEF SUMMARY

Group III oxide semiconducting devices with effective device isolation and edge termination regions are presented hereinbelow.

In one or more instantiations, the Group III oxide semiconducting device includes a Group III-oxide layer extending from a bottom distal surface to a top distal surface and from a first side surface, extending from the bottom distal surface to the top distal surface, to a second side surface, extending from the bottom distal surface to the top distal surface, and at least one deep acceptor doped region, on a region of the Group III-oxide layer, the at least one deep acceptor doped region comprising one or more regions extending from the first side surface to a Group III-oxide semiconductor structure, a region extending from the second side surface the Group III-oxide semiconductor structure or another Group III-oxide semiconductor structure, a region extending between two Group III-oxide semiconductor structures, or a region extending between two Group III-oxide semiconductor sub-devices. In one instance, deep acceptors do not include Magnesium (Mg) or Nitrogen (N). In another instance, the at least one deep acceptor can include iron (Fe), Copper (Cu), Zinc (Zn) and Cobalt (Co).

For a better understanding of the present teachings, together with other and further objects thereof, reference is made to the accompanying drawings and detailed description and its scope will be pointed out in the appended claims.

### BRIEF DESCRIPTION OF THE DRAWINGS

FIG. 1A is a graphical representation of an instantiation of the device of these teachings;

FIG. 1B is a graphical representation of another instantiation of the device of these teachings;

FIG. 1C is a graphical representation of yet another instantiation of the device of these teachings;

FIG. 1D is a graphical representation of yet another instantiation of the device of these teachings;

FIG. 1E is a graphical representation of yet another instantiation of the device of these teachings;

FIG. 1F is a graphical representation of a Nitrogen implanted device used in these teachings;

FIG. 1G is a graphical representation of an Iron implanted device used in these teachings;

FIG. 2A is a graphical representation of variations on one instantiation of the device of these teachings;

FIG. 2B is a graphical representation of variations on another instantiation of the device of these teachings;

FIG. 2C is a graphical representation of further variations on said another instantiation of the device of these teachings;

FIG. 2D is a graphical representation of further variations on said one instantiation of the device of these teachings; and

FIG. 2E is a graphical representation of variations on yet another instantiation of the device of these teachings.

### DETAILED DESCRIPTION

The following detailed description presents the currently contemplated modes of carrying out these teachings. The description is not to be taken in a limiting sense but is made merely for the purpose of illustrating the general principles of these teachings, since the scope of these teachings is best defined by the appended claims.

“Doping'” as used herein, refers to the introduction of foreign elements (not found in the pure semiconductor crystal), into the semiconductor crystal. The introduction of foreign elements can be achieved by diffusion or ion implantation. Techniques such as ion implantation, diffusion, Chemical Vapor Deposition (CVD), Molecular Beam Epitaxy (MBE), and Pulsed Laser Deposition (PLD) ion implantation, diffusion, are typically used to create selective area doping, but these teachings are not limited to only those techniques. (See, for example, Wafer Fabrication: Doping techniques, available at www.halbleiter.org/en/waferfabrication/doping/.)

An “acceptor,” as used herein, is a dopant atom that when substituted into a semiconductor lattice may form a p-type region.

A “deep acceptor,” as used herein, is an acceptor having acceptor energy levels that are too far from the valence band to give rise to free holes.

Studies indicate that conventional acceptor doping may not lead to p-type conductivity, since all acceptors are too deep to give rise to free holes. However, incorporating acceptor impurities can still be useful for creating semi-insulating material (controlling electrical conductivity), which can be used in devices with effective device isolation and edge termination. Edge termination requires complementary/compensating dopants, precise spatial control of doping, and known behavior of edge material. Device isolation requires minimal leakage current that is robust to frequency and temperature. Complementary doping can deplete drift regions and create resistive regions to block current.

Deep acceptor doping by Nitrogen implantation has been demonstrated (see, for example, Wong, M. H. et al. (2018), Applied Physics Letters, 113(10), 102103), but blocking was assessed only under DC conditions. Nitrogen was found to exhibit much lower thermal diffusivity than Magnesium (Mg), which enables the use of higher annealing temperatures to maximize N activation efficiency without significantly altering the impurity profile. Significant long-lasting charge trapping in N-implanted layers has been shown (see, for example, Fregolent, M. et al. (2021), Journal of Applied Physics, 130(24), 2457040) but the observed ˜0% trapped charge at 0.1s implies a frequency above which blocking is not realized.

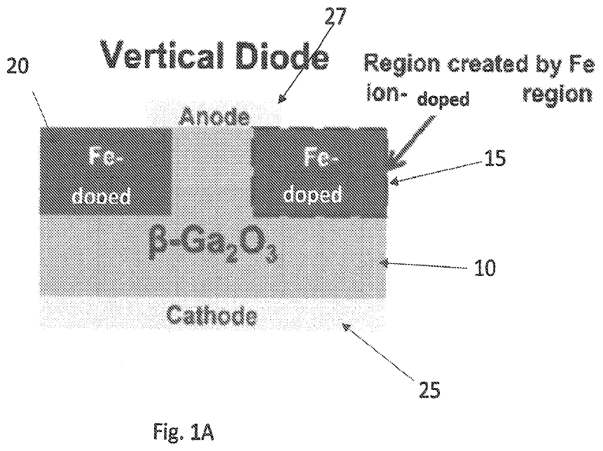

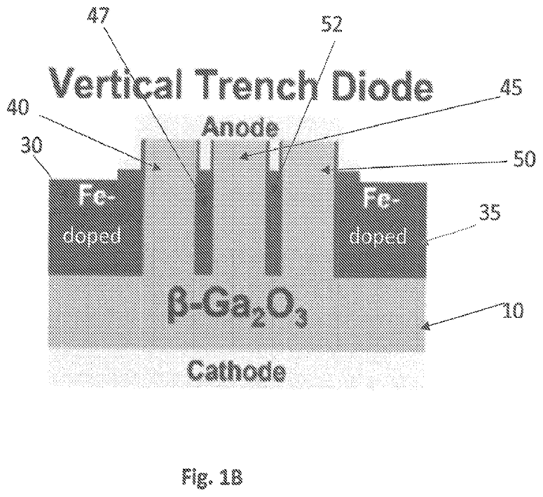

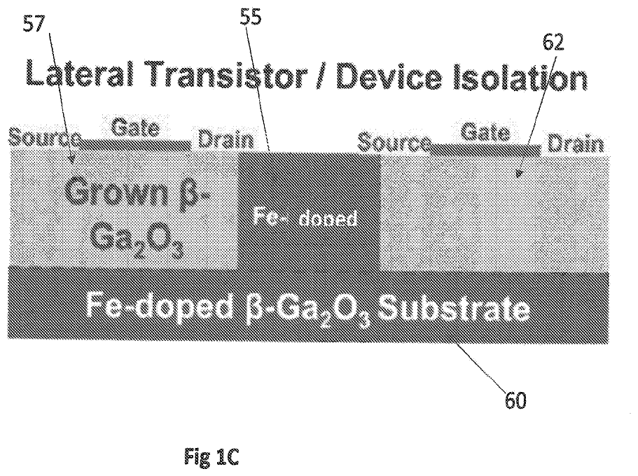

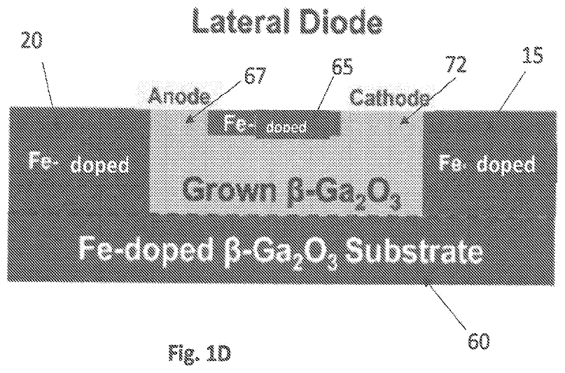

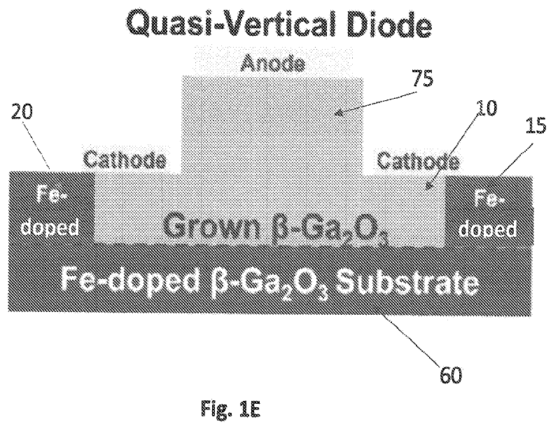

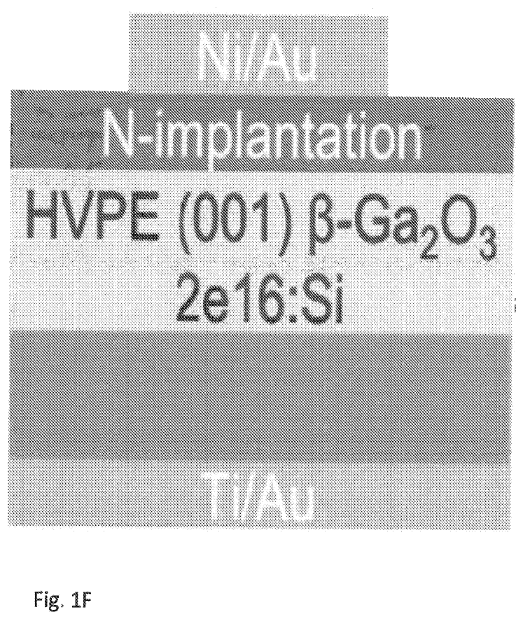

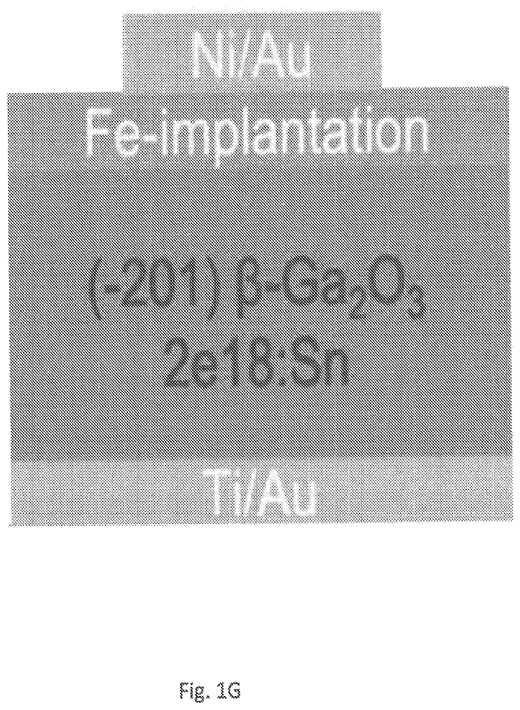

The devices shown in FIGS. 1F and 1G were fabricated (including annealing)in order to determine the frequency dependent behavior of nitrogen implanted and ion implanted III-oxide devices. Measurements indicated that nitrogen implanted device exhibits similar DC and pulsed I-V characteristics and that on the DC conditions the nitrogen planted layer blocks current.

However, under pulsed conditions, the nitrogen implanted layer, and a long time reduces only forward current and at very short times, the nitrogen implanted layer acts transparent to current conduction. Measurements also indicate that the iron implanted also blocks current on the DC conditions. Under pulsed conditions, the iron implanted layer blocks current bolts in the forward and reverse direction and the current blocking is maintained in the high frequency measurement.

“III,” as used herein, refers to one of the semiconducting elements and Aluminum or a combination of semiconducting elements and Aluminum or Aluminum from group III. Of the Group III elements, one skilled in the art would know that boron trioxide is not a semiconductor (Boron trioxide is almost always found as the vitreous (amorphous) form; however, it can be crystallized after extensive annealing (that is, under prolonged heat). See www.chemeurope.com/en/encyclopedia/Boron_trioxide.html).) One skilled in the art would also know that thallium trioxide can be a degenerate (very highly doped) semiconductor (see, Richard J. Phillips et al., Electrochemical and photoelectrochemical deposition of thallium(III) oxide thin films, Journal of Materials Research 4, 923-929 (1989) and H. P. Geserich, Phys. Status Solidi 25, 741 (1968) ) and is unlikely to be used in a transistor. One skilled in the art would know that Nihonium (the element formerly known as ununtrium) has not been seen as having any oxides since the most stable isotope of Nihonium (Nihonium-286) has a half-life of around 8 seconds and decays into Roentgenium, which is also unstable and part of the copper group (See periodic-table.com/nihonium/).)

In one or more instantiations, the Group III oxide semiconducting device includes a Group III-oxide layer extending from a bottom distal surface to a top distal surface and from a first side surface, extending from the bottom distal surface to the top distal surface, to a second side surface, extending from the bottom distal surface to the top distal surface, and at least one deep acceptor doped region, doped on a region of the Group III-oxide layer, the at least one deep acceptor doped region comprising one or more of a region extending from the first side surface to a Group III-oxide semiconductor structure, a region extending from the second side surface the Group III-oxide semiconductor structure or another Group III-oxide semiconductor structure, a region extending between two Group III-oxide semiconductor structures, or a region extending between two Group III-oxide semiconductor sub devices.

In one instance, the at least one deep acceptor is not Magnesium (Mg) or Nitrogen (N). In another instance, the at least one deep acceptor can include at least one of iron (Fe), Copper (Cu), Zinc (Zn) or Cobalt (Co).

In one instance, a doping depth of the at least one deep acceptor doped region is between about 5 nm to several um.

Activation temperature may vary. Typically, activation temperature is 950° C. but can vary from about 400 °C. to about 1500° C.

Doping with deep acceptors can be performed in multiple steps, where each doping step can have a different concentration of deep acceptor.

In another instance, a width of the at least one deep acceptor doped region varies with distance from the top distal surface. The variation of the width can result from doping (typically, when doping is by implantation) of the deep acceptor at a predetermined angle with respect to the substrate.

In yet another instance, a concentration of the at least one deep acceptor doped region varies with distance from the top distal surface. The concentration of the at least one deep acceptor doped region can vary from about 1×10¹⁶ cm⁻³ to about 5×10²⁰ cm⁻³. Typically, the concentration of the at least one deep acceptor doped region is 5±3×10¹⁸ cm⁻³.

In still another instantiation, the concentration of the at least one deep acceptor doped region is greater than the concentration of carriers in the Group III-oxide layer.

In order to further elucidate these teachings, an illustrative instantiation, in which the group III-oxide semiconductor material is Ga2O3, and the deep acceptor is Fe, is presented herein below. It should be noted that these teachings are not limited to only this instantiation.

In one instance, in the Group III-oxide semiconductor device of theses teachings, the at least one deep acceptor doped region includes a first deep acceptor doped region extending from the first side surface to a first side surface of the Group III-oxide semiconductor structure, the Group III-oxide semiconductor structure being an upstanding channel and a second deep acceptor doped region. In the first deep acceptor doped region, the upstanding channel extends to the distal top surface, and extends from the distal top surface to a third distal surface, where the third distal surface is disposed between the distal top surface and the bottom distal surface. The second deep acceptor doped region extends from the second side surface to a second side surface of the Group III-oxide semiconductor structure, and from the distal top surface to the third distal surface. FIG. 1A shows the above described instantiation where deep acceptor is Iron (Fe).

Referring to FIG. 1A, in the instantiation shown therein, one Fe doped region 20 extends from the first side surface to the upstanding channel (the Group III-oxide semiconductor structure), and another Fe doped region 15 extends from the second side surface to on the other side of the Group III-oxide semiconductor structure. The Fe doped region extends from a distal top surface to a third distal surface, the third distal surface being disposed between the distal top surface and a bottom distal surface. An electrically conductive layer 27 is disposed on the distal top surface section of the upstanding channel. Another electrically conductive layer 25 is disposed on the bottom distal surface section of the Group III-oxide layer. (Electrically conductive layers, as used herein, includes layers of a material selected such that a potential barrier between electrically conductive layer and the Group III-oxide semiconductor is low enough for electrical conduction.) Examples of electrically conductive layers include Titanium (Ti) and Indium-tin oxide (ITO), but these teachings are not limited to only those examples. The Group III-oxide layer 10 extends from the bottom distal surface to the top distal surface and from a first side surface, the Group III-oxide layer extending from the bottom distal surface to the top distal surface, to the second side surface, the Group III-oxide layer extending from the bottom distal surface to the top distal surface.

Although the device shown in FIG. 1A is a Schottky diode, PN diodes and other junctions including metal-insulator-semiconductors etc. are also the scope of these teachings. In the PN diode instantiation, the Group III-oxide semiconductor structure is an upstanding channel with a p-type heterojunction. Examples of p-type heterojunctions include GaN/Ga₂O₃ or NiOₓ/Ga₂O₃, but these teachings are not limited to only those examples.

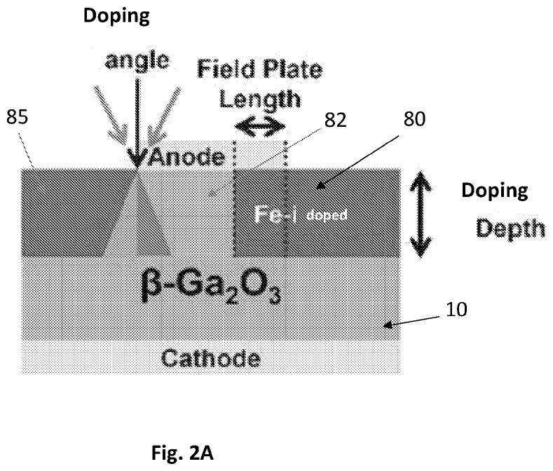

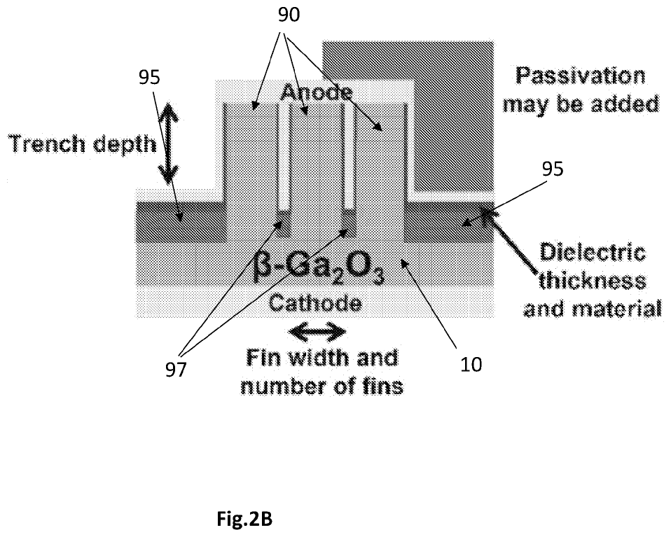

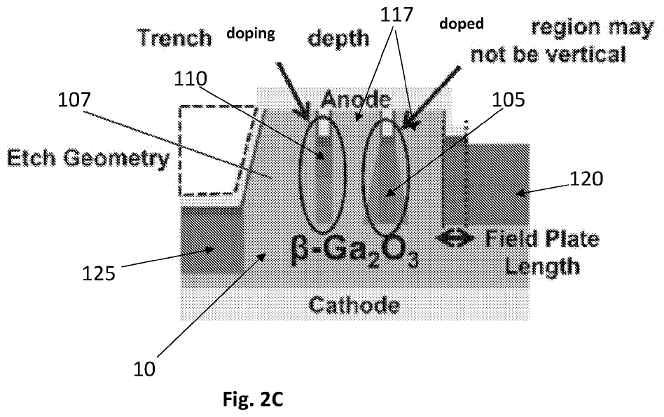

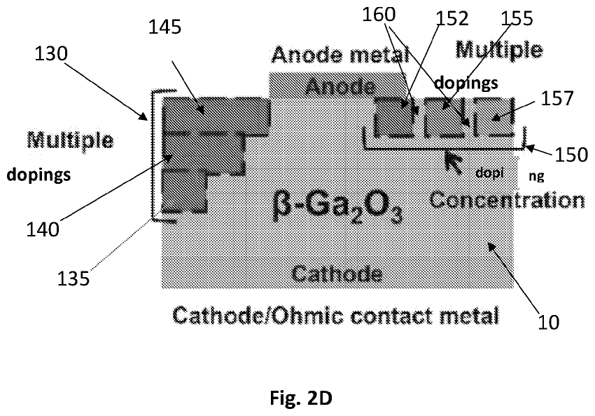

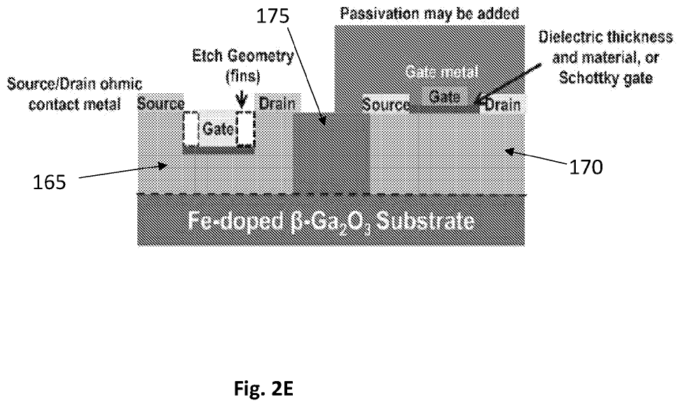

In some instances, such as shown in FIG. 2A, at least one of the first side surface of the Group III-oxide semiconductor structure and the second side surface of the Group III-oxide semiconductor structure is inclined with respect to a surface perpendicular to the distal top surface.

In another instantiation of the Group III-oxide semiconductor device of these teachings, the Group III-oxide semiconductor structure comprises a number of channels; the number of channels extending from a middle distal surface located between the bottom distal surface and a first intermediate distal surface. In another instantiation of the Group III-oxide semiconductor device of these teachings, the Group III-oxide semiconductor structure has a number of channels, the number of channels extending from a middle distal surface located between the bottom distal surface and a first intermediate distal surface. In one instance, the least one deep acceptor doped region includes a first deep acceptor doped region, a number of deep acceptor doped regions and a last deep acceptor doped region. The first deep acceptor doped region extends from the middle distal surface to a top distal surface and from the first side surface, extends from the middle distal surface to the top distal surface, to a first side surface of a first channel from the number of channels, and extends from the middle distal surface to the top distal surface. Each one of the number of deep acceptor doped regions extends from the middle distal surface to a second intermediate distal surface and from a second side surface of a preceding channel of the number of channels, extending from the middle distal surface to the second intermediate distal surface, to a first side surface of a subsequent channel of the number of channels, extending from the middle distal surface to the second intermediate distal surface. In some instances, the first intermediate distal surface is located above the top distal surface. In other instances, the second intermediate distal surface is located at the top distal surface and the third intermediate distal surface is located at the top distal surface.

In yet other instances, as shown in FIG. 2C, in at least one of the number of deep acceptor doped regions, a doping concentration varies along a distance from the middle distal surface to the second intermediate distal surface.

In still other instances, as shown in FIG. 2C, at least a portion of at least one side surface of at least one channel from the number of channels is inclined with respect to a surface perpendicular to the middle distal surface.

Instantiations are also possible in which the first deep acceptor doped region extends from a second intermediate distal surface to a third intermediate distal surface and from the first side surface, extending from the second intermediate distal surface to the third intermediate distal surface, to a first side surface of the first channel from the number of channels, extending from the second intermediate distal surface to the third intermediate distal surface, each one of the number of deep acceptor doped regions extends from a middle distal surface to a top distal surface and from a second side surface of a preceding channel of the number of channels, which extends from the middle distal surface to the top distal surface, to a first side surface of a subsequent channel of the number of channels, which extends from the middle distal surface to the top distal surface. The variation in instances described hereinabove is also possible for those instantiations. FIG. 1B shows the above described instantiation in which the Group III-oxide semiconductor structure comprises a number of channels. In FIG. 1B, the deep acceptor is Iron (Fe).

Referring to FIG. 1B, in the instantiation shown therein, one Fe doped region 30 extends from the first side surface to a first Group III-oxide semiconductor structure 40, where the Group III-oxide semiconductor structures are a number of upstanding channels 40, 45, 50, and another Fe doped region 35 extends from the second side surface to the second side surface on the last of the Group III-oxide semiconductor structures 50. The Fe doped regions extend from a third distal surface to a location inside the Group III-oxide layer, the third distal surface being located between the distal top surface and the distal bottom surface. Each one from a number of other Fe doped regions 47, 52 extends from a side surface of one of the upstanding channels 40, 45 to an opposing side surface of a next upstanding channel 45, 50. A dielectric layer is disposed on the side surfaces of the upstanding channels, on the third distal surface of each of the number of Fe doped regions 47, 52, on a portion of the one Fe doped region 30 extending from a location between the first side surface and a side surface, opposite to the first side surface, of the first one 40 of the upstanding channels, and on a portion of the another Fe doped region 35 extending from a side surface of the last one of the upstanding channels, the side surface of the last one of the upstanding channels being opposite to the second sides surface, the section extending from a location between the second side surface and the side surface of the last one of the upstanding channels to the side surface of the last one of the upstanding channels. An electrically conductive layer is disposed on the portion of the upstanding channels extending from the third distal surface to the distal top surface and on the dielectric layer. Another electrically conductive layer 25 is disposed on the bottom distal surface section of the Group III-oxide layer. The dielectric layer thickness and material can vary depending on the device on structures. Dielectric layer thickness can vary between about 1 nm and about 1000 nm. Typically, a dielectric layer thickness varies between about 5 nm and about 30 nm. Examples of dielectric material include aluminum oxide (Al₂O₃), silicon dioxide (SiO₂), and Hafnium oxide (HfO₂), although these teachings are not limited only to those examples.

In a number of instantiations, the bottom distal surface of the Group III-oxide layer is disposed over a deep acceptor doped III-oxide substrate.

In one of the number of instantiations, Group III-oxide semiconductor device includes first and second Group III-oxide semiconductor structures, each one of the first and second Group III-oxide semiconductor structures formed in a separate region of the Group III-oxide layer; and wherein the at least one deep acceptor doped region extends for the first Group III-oxide semiconductor structure to the second Group III-oxide semiconductor structure. In one instance, the first Group III-oxide semiconductor structure extends from the first side surface to a first intermediate side surface, the second Group III-oxide semiconductor structure extends from a second intermediate side surface to the second side surface, and the at least one deep acceptor doped region comprises a deep acceptor doped region extending from the first intermediate side surface to the second intermediate side surface. The first Group III-oxide semiconductor structure extends from the first side surface to a first intermediate side surface, the second Group III-oxide semiconductor structure extends from a second intermediate side surface to the second side surface, and the at least one deep acceptor doped region includes a deep acceptor doped region extending from the first intermediate side surface to the second intermediate side surface.

Referring to FIG. 1C, in the instantiation shown therein, a Fe doped region 55 extends from one side of one Group III-oxide semiconductor sub-device 57 to a side of another Group III-oxide semiconductor sub-device 62, the side of the other Group III-oxide semiconductor sub-device being opposite to the one side of the one Group III-oxide semiconductor sub-device, and also extends from the distal top surface to the bottom distal surface. A Fe-doped β-Ga₂O₃ substrate layer 60 is disposed on the bottom distal surface of the two Group III-oxide semiconductor sub-devices in the Fe dopped region. In the instantiation shown in FIG. 1C. The two Group III-oxide semiconductor sub-devices are FETs. A source electrically conductive layer is disposed on one portion of the distal top surface of each of the Group III-oxide semiconductor sub-devices and a drain electrically conductive layer disposed on another portion of the distal top surface of each of the Group III-oxide semiconductor sub-devices, the other portion being separate and opposite from the portion. A dielectric layer is disposed on the distal top surface of each of the Group III-oxide semiconductor sub-devices and between the source electrically conductive layer and the drain electrically conductive layer. In each of the two Group III-oxide semiconductor sub-devices a gate electrically conductive layer is disposed on the dielectric layer and separate from the source electrically conductive layer and the drain electrically conductive layer.

In another of the number of instantiations, the Group III-oxide semiconductor structure extends from a first intermediate side surface to a fourth intermediate side surface and has an indented region extending from a second intermediate side surface to a third intermediate side surface, the indented region extending from a middle distal surface to the bottom distal surface. The Group III-oxide semiconductor structure has a first pillar extending from the intermediate first side surface to a second intermediate side surface, and a second pillar extending from a third intermediate side surface to the fourth intermediate side surface. The at least one deep acceptor doped region includes a first deep acceptor doped region extending from the first side surface to a first intermediate side surface, and a second deep acceptor doped region extending from a fourth intermediate side surface to the second side surface. The at least one deep acceptor doped region also includes a third deep acceptor doped region disposed between the first deep acceptor doped region and the second deep acceptor doped region and extending from the second intermediate side surface to the third intermediate side surface, and from the middle distal surface to the top distal surface, the middle distal surface located between the bottom distal surface and the top distal surface.

Referring to FIG. 1D, in the instantiation shown therein, a first Fe doped region 20 extends from the first side surface to a side surface of a first Group III-oxide semiconductor structure, the first Group III-oxide semiconductor structure 67 connecting to an anode electrically conducting layer, a second Fe doped region 15 extends from the second side surface to a side surface of the second Group III-oxide semiconductor structure, the second Group III-oxide semiconductor structure 72 connecting to a cathode electrically conducting layer, and a third Fe doped region 65 extends from another side surface of the first Group III-oxide semiconductor structure 67 to another side surface of the second Group III-oxide semiconductor structure 72, the another side surface of the second Group III-oxide semiconductor structure 72 being opposite the another side surface of the first Group III-oxide semiconductor structure 67. The first and second Fe doped regions 20, 15 extend from the distal top surface to the bottom distal surface. The third Fe doped region 65 extends from the distal top surface to a location between the distal top surface and the bottom distal surface. The anode electrically conductive layer is disposed on the first Group III-oxide semiconductor structure 67 at the distal top surface. The cathode electrically conductive layer is disposed on the second Group III-oxide semiconductor structure 72 as the distal top surface. An Fe-doped β-Ga₂O₃ substrate layer 60 is disposed on the bottom distal surface of the Group III-oxide layer 10 and on the first and second Fe doped regions 20, 15.

In yet another of the number of instantiations, the Group III-oxide semiconductor structure extends from a first intermediate side surface to a second intermediate side surface, and has a Group III-oxide semiconductor pillar is disposed on the top distal surface of the Group III-oxide layer; a first side surface of the Group III-oxide semiconductor pillar disposed a distance away from the first intermediate side surface, a second side surface of the Group III-oxide semiconductor pillar disposed a distance away from the second intermediate side surface. The at least one deep acceptor doped region has a first deep acceptor doped region extending from the first side surface to a first intermediate side surface, and a second deep acceptor doped region extending from a second intermediate side surface to the second side surface.

Referring to FIG. 1E, in the instantiation shown therein, one Fe doped region 20 extends from the first side surface to a side surface of the Group III-oxide layer 10 and another Fe doped region 15 extends from the second side surface to another side surface of the Group III-oxide layer 10. The one Fe doped region 20 and the another Fe doped region 15 extend from the top distal surface to the bottom distal surface. An upstanding Group III-oxide channel 70 extends from the distal top surface to the third distal surface. A first (cathode) electrically conductive layer is disposed on the top distal surface extending from a first side surface of the Group III-oxide layer 10 to a location away from the upstanding Group III-oxide channel 75. The second (cathode) electrically conductive layer is disposed on the top distal surface extending from the second side surface of the Group III-oxide layer 10 to a location away from the upstanding Group III-oxide channel 75. A third (anode) electrically conductive layer is disposed over the upstanding Group III-oxide channel 75 at the third distal surface. In the instantiation shown in FIG. 1E, the first and second electrically conductive layers are electrically conductive layers for the cathode and the third electrically conductive layer is an electrically conductive layer for the anode. A Fe-doped β-Ga₂O₃ substrate layer 60 is disposed on the bottom distal surface of the Group III-oxide layer 10 and on the Fe doped regions 15, 20.

A number of variations of the instantiations shown in FIGS. 1A-1E are shown in FIGS. 2A-2E. Referring to FIG. 2A, in the instantiation shown therein, a variation of the instantiation shown in FIG. 1A is shown. In the variation shown in FIG. 2A, the one Fe doped region 85 has a varying width, the width varying with distance from the top distal surface. The variation of the width can result, for example, when deposition is by ion implantation, from doping of the Fe at a predetermined angle with respect to a line on the bottom distal surface and is defined in a plane normal to the bottom distal surface. The predetermined angle is between 0-180 degrees, preferably 45-135 degrees. (Alternatively, the predetermined angle is defined with respect to a line perpendicular to the bottom distal surface and a line in a plane perpendicular to the bottom distal surface. Such angles will be complementary to the angles in the previous definition and the same ranges apply,) The width of the upstanding channel 82 also varies with distance from the top distal surface, the variation of the width of the upstanding channel being complementary (or opposite) to the variation of the width of the one Fe doped region 85. A field plate layer is disposed on the another Fe doped region 80 at the distal top surface and in electrical contact with the electrically conductive layer disposed on the upstanding channel. The field plate is electrically conductive.

Referring to FIG. 2B, in the instantiation shown therein, a variation of the instantiation shown in FIG. 1B is shown. In the variation shown in FIG. 2B, the dielectric layer is disposed on the side surfaces of the upstanding channels 90 and on the third distal surface of each of the number of Fe doped regions 95. The electrically conductive layer is disposed on the dielectric layer and on the distal top surface oof the upstanding channels 90. A passivation layer is disposed over of a portion of the electrically conductive layer on the distal top surface of the upstanding channels, the portion extending from approximately a center of the electrically conductive layer on the distal top surface of the upstanding channels to the side surface over the last upstanding channel, and on the dielectric layer over the another Fe doped region 95. In another instantiation, the passivation layer is disposed over of a portion of the electrically conductive layer on the distal top surface of the upstanding channels, the portion extending from approximately a center of the electrically conductive layer on the distal top surface of the upstanding channels to the side surface over the first upstanding channel, and on the dielectric layer over the one Fe doped region. Examples of passivation layer materials include alumina (Al₂O₃), silicon dioxide (SiO₂), Flourinert, and SU-8, but these teachings are not limited only to those examples.

Referring to FIG. 2C, in the instantiation shown therein, another variation of the instantiation shown in FIG. 1B is shown. In the variation shown in FIG. 2C, the one Fe doped region 125 extends from a fourth distal surface to the bottom distal surface, the fourth distal surface being between the third distal surface and the bottom distal surface. A width of the first upstanding channel 107 varies from a larger width at the fourth distal surface to a smaller width at the distal top surface. Some or all of the number of other Fe doped regions 110, 105, 120 can have varying width, the width varying from the fourth distal surface to the third distal surface. Some or all of the number of other Fe doped regions 110, 105, 120 may not be completely vertical. The dielectric layer is disposed over the one Fe doped region at the fourth distal surface, over the sides of the upstanding channels 107, 117 from the distal top surface to the surface of the one Fe doped channel 125 at the fourth distal surface, from the distal top surface to the surface of the number of other Fe doped regions 105, 110 and over a portion of the another Fe doped region 120 at the third distal surface, the portion extending from the side surface of the last upstanding channel 117 to a location between the side surface of the last upstanding channel 117 and the second side surface of the Group III-oxide layer 10.

In a further instantiation, the at least one deep acceptor doped region includes a number of deep acceptor doped sub-regions. In one instance, deep acceptor doped sub-regions, from a second sub-region to a next to last sub-region, are each disposed on a previous sub-region. In another instance, each sub-region has a doping concentration for said each sub-region. In yet another instance, each sub-region has a doping concentration for said each sub-region. In a further instance, each sub-region, for a second sub-region to a last sub-region, has a first side surface of said each sub-region is substantially parallel to a first side surface for a first sub-region, and a second side surface of each sub-region is substantially parallel to a first side surface for a first sub-region. In some instantiations, each sub-region has a doping concentration for that sub-region. In one instance, each sub-region extends from a middle distal surface to the top distal surface. In a further instance, a Group III-oxide semiconductor pillar is disposed between each two subsequent sub regions.

Referring to FIG. 2D, in the instantiation shown therein, another variation of the instantiation shown in FIG. 1A is shown. In the variation shown in FIG. 2D, the one Fe doped region 130 includes a number of sub-regions of different widths 135, 140, 145. In the instantiation shown, the first sub-region of narrower width 135 is disposed on the third distal surface. The width of the subsequent sub-regions 140, 145 increases from the first sub-region up 135 to the distal top surface. The another Fe doped region 150 includes a number of other sub-regions 152, 155, 157 extending from the distal top surface to a fourth distal surface, the fourth distal surface located between the distal top surface and the third distal surface. The first of the other sub-regions extends from the second side surface of the Group III-oxide layer 10 to a distance between the second side surface of the Group III-oxide semiconductor structure and the second side surface of the Group III-oxide layer 10. Subsequent of the other sub-regions are disposed adjacent to each other up to the second side surface of the Group III-oxide layer. Each one of the other sub-regions may have a different Fe concentration. A Group III-oxide semiconductor pillar 160 is disposed between each two subsequent sub-regions.

Referring to FIG. 2E, in the instantiation shown therein, another variation of the instantiation shown in FIG. 1C is shown. In the variation shown in FIG. 2E, the first Group III-oxide semiconductor structure 165 extends from the first side surface to a first intermediate side surface, the second Group III-oxide semiconductor structure 170 extends from a second intermediate side surface to the second side surface, and the at least one deep acceptor doped region 175 has a deep acceptor doped region extending from the first intermediate side surface to the second intermediate side surface. the first Group III-oxide semiconductor structure has an indented region extending from a third intermediate side surface to a fourth intermediate side surface, the indented region extending from a middle distal surface to the bottom distal surface; the indented region producing two pillars, one pillar extending from the first side surface to the third intermediate side surface, and a second pillar extending from the fourth intermediate side surface to the first intermediate side surface.

In FIGS. 1B, 2B and 2C, a height of any of the upstanding channels (sometimes referred to as “fins”) is between about 50 nm-about 10 μm, preferably between about 400 nm to about 2 μm. A distance between any two of the upstanding channels (sometimes referred to as a width of the “trench”) is between about 10 nm to about 50 μm, preferably between about 100 nm to about 5 μm. The “trench depth” in FIG. 2B refers to the distance between the original top distal surface and the new surface created via selectively removing material. The “trench doped depth” in FIG. 2C refers to the depth at which the Fe is doped.

As used herein, the singular forms “a,” “an,” and “the” include the plural reference unless the context clearly dictates otherwise. Except where otherwise indicated, all numbers expressing quantities of ingredients, reaction conditions, and so forth used in the specification and claims are to be understood as being modified in all instances by the term “about.”

For the purpose of better describing and defining the present teachings, it is noted that terms of degree (e.g., “substantially,” “about,” and the like) may be used in the specification and/or in the claims. Such terms of degree are utilized herein to represent the inherent degree of uncertainty that may be attributed to any quantitative comparison, value, measurement, and/or other representation. The terms of degree may also be utilized herein to represent the degree by which a quantitative representation may vary (e.g., ±10%) from a stated reference without resulting in a change in the basic function of the subject matter at issue.

Although these teachings have been described with respect to various instantiations, it should be realized these teachings are also capable of a wide variety of further and other instantiations within the spirit and scope of the appended claims.

What is claimed is:

1. A Group III-oxide semiconductor device comprising:
a Group III-oxide layer extending from a bottom distal surface to a top distal surface and from a first side surface, extending from the bottom distal surface to the top distal surface, to a second side surface, extending from the bottom distal surface to the top distal surface; and
at least one deep acceptor doped region, doped on a region of the Group III-oxide layer, the at least one deep acceptor doped region comprising one or more of more of a region extending from the first side surface to a Group III-oxide semiconductor structure, a region extending from the second side surface to another Group III-oxide semiconductor structure, or a region extending between two Group III-oxide semiconductor structures; wherein a deep acceptor is not Magnesium (Mg) or Nitrogen (N).

2. The Group III-oxide semiconductor device of claim 1 wherein a depth of at least one deep acceptor doped region is from about 5 nm to about 10 μm.

3. The Group III-oxide semiconductor device of claim 1 wherein a depth of at least one deep acceptor doped region is from about 50 nm to about 5 μm.

4. The Group III-oxide semiconductor device of claim 1, wherein the at least one deep acceptor doped region has a deep acceptor concentration from about 1×10¹⁶ cm−3 to about 5×10²⁰ cm⁻³.

5. The Group III-oxide semiconductor device of claim 1, wherein the at least one deep acceptor doped region has a deep acceptor concentration greater than a concentration of carriers in the Group III-oxide layer.

6. The Group III-oxide semiconductor device of claim 1 wherein at least one deep acceptor doped region comprises two or more layers with different deep acceptor concentration between layers or different length, width, depth, and/or areas between two adjacent layers.

7. The Group III-oxide semiconductor device of claim 1, further comprising one or more electrically conducting layers.

8. The Group III-oxide semiconductor device of claim 1, wherein the at least one deep acceptor doped region is in contact with at least one of a deep acceptor doped Gallium oxide structure or a non-deep acceptor-doped Gallium oxide structure.

9. The Group III-oxide semiconductor device of claim 1, wherein the at least one deep acceptor doped region is in contact with at least one of a deep acceptor doped Gallium oxide structure or a non-deep acceptor doped Gallium oxide structure.

10. The Group III-oxide semiconductor device of claim 1, wherein deep acceptor comprises at least one of iron (Fe), Copper (Cu), Zinc (Zn) or Cobalt (Co).

11. The Group III-oxide semiconductor device of claim 1, wherein deep acceptor comprises at least one of iron (Fe), Copper (Cu) or Cobalt (Co).

12. The Group III-oxide semiconductor device of claim 1, wherein deep acceptor is Iron (Fe).

13. The Group III-oxide semiconductor device of claim 1, wherein the at least one deep acceptor doped region comprises:
a first deep acceptor doped region extending from the first side surface to a first side surface of the Group III-oxide semiconductor structure, the Group III-oxide semiconductor structure being an upstanding channel, the upstanding channel extending to the distal top surface, and extending from the distal top surface to a third distal surface; the third distal surface being disposed between the distal top surface and the bottom distal surface;
and a second deep acceptor doped region extending from the second side surface to a second side surface of the Group III-oxide semiconductor structure, and from the distal top surface to the third distal surface.

14. The Group III-oxide semiconductor device of claim 13, wherein the deep acceptor is Iron (Fe).

15. The Group III-oxide semiconductor device of claim 13, wherein at least one of the first side surface of the Group III-oxide semiconductor structure and the second side surface of the Group III-oxide semiconductor structure, is inclined with respect to a surface perpendicular to the distal top surface.

16. The Group III-oxide semiconductor device of claim 15, wherein the deep acceptor is Iron (Fe).

17. The Group III-oxide semiconductor device of claim 1, wherein the Group III-oxide semiconductor structure comprises a number of channels; the number of channels extending from a middle distal surface located between the bottom distal surface and a first intermediate distal surface.

18. The Group III-oxide semiconductor device of claim 17, wherein the least one deep acceptor doped region comprises:
a first deep acceptor doped region extending from the middle distal surface to a top distal surface and from the first side surface, extending from the middle distal surface to the top distal surface, to a first side surface of a first channel from the number of channels, extending from the middle distal surface to the top distal surface;
a number of deep acceptor doped regions, each one of the number of deep acceptor doped regions extending from the middle distal surface to a second intermediate distal surface and from a second side surface of a preceding channel of the number of channels, extending from the middle distal surface to the second intermediate distal surface, to a first side surface of a subsequent channel of the number of channels, extending from the middle distal surface to the second intermediate distal surface; and
a last deep acceptor doped region extending from the middle distal surface to a third intermediate distal surface and from the second side surface, extending from the middle distal surface to the third intermediate distal surface, to a second side surface of a last channel from the number of channels, extending from the middle distal surface to the third intermediate distal surface.

19. The Group III-oxide semiconductor device of claim 18, wherein the first intermediate distal surface is located above the top distal surface.

20. The Group III-oxide semiconductor device of claim 19, wherein the second intermediate distal surface is located at the top distal surface; and wherein the third intermediate distal surface is located at the top distal surface.

21. The Group III-oxide semiconductor device of claim 18, wherein at least a portion of at least one side surface of at least one channel from the number of channels is inclined with respect to a surface perpendicular to the middle distal surface.

22. The Group III-oxide semiconductor device of claim 18, wherein, in at least one of the number of deep acceptor doped regions, a doping concentration varies along a distance from the middle distal surface to the second intermediate distal surface.

23. The Group III-oxide semiconductor device of claim 17, wherein the least one deep acceptor doped region comprises:
a first deep acceptor doped region extending from a second intermediate distal surface to a third intermediate distal surface and from the first side surface, extending from the second intermediate distal surface to the third intermediate distal surface, to a first side surface of a first channel from the number of channels, extending from the second intermediate distal surface to the third intermediate distal surface;
a number of deep acceptor doped regions, each one of the number of deep acceptor doped regions extending from a middle distal surface to a top distal surface and from a second side surface of a preceding channel of the number of channels, extending from the middle distal surface to the top distal surface, to a first side surface of a subsequent channel of the number of channels, extending from the middle distal surface to the top distal surface; and
a last deep acceptor doped region extending from the middle distal surface to a top distal surface and from the second side surface, extending from the middle distal surface to a fourth intermediate distal surface, to a second side surface of a last channel from the number of channels, extending from the middle distal surface to the top distal surface.

24. The Group III-oxide semiconductor device of claim 23, wherein the first intermediate distal surface is located above the top distal surface.

25. The Group III-oxide semiconductor device of claim 24, wherein the second intermediate distal surface is located below the top distal surface; and wherein the third intermediate distal surface is located below the top distal surface.

26. The Group III-oxide semiconductor device of claim 23, wherein at least a portion of at least one side surface of at least one channel from the number of channels is inclined with respect to a surface perpendicular to the middle distal surface.

27. The Group III-oxide semiconductor device of claim 23, wherein, in at least one of the number of deep acceptor doped regions, a doping concentration varies along a distance from the middle distal surface to the top distal surface.

28. The Group III-oxide semiconductor device of claim 1, wherein the bottom distal surface of the Group III-oxide layer is disposed over a deep acceptor doped III-oxide substrate.

29. The Group III-oxide semiconductor device of claim 28, comprising a first and second Group III-oxide semiconductor structures, each one of the first and second Group III-oxide semiconductor structures formed in a separate region of the Group III-oxide layer; and
wherein the at least one deep acceptor doped region extends for the first Group III-oxide semiconductor structure to the second Group III-oxide semiconductor structure.

30. The Group III-oxide semiconductor device of claim 29, wherein the first Group III-oxide semiconductor structure extends from the first side surface to a first intermediate side surface, the second Group III-oxide semiconductor structure extends from a second intermediate side surface to the second side surface, and the at least one deep acceptor doped region comprises a deep acceptor doped region extending from the first intermediate side surface to the second intermediate side surface.

31. The Group III-oxide semiconductor device of claim 30, wherein said deep acceptor doped region extends from the bottom distal surface to the top distal surface.

32. The Group III-oxide semiconductor device of claim 28, wherein the Group III-oxide semiconductor structure extends from a first intermediate side surface to a fourth intermediate side surface and has an indented region extending from a second intermediate side surface to a third intermediate side surface, the indented region extending from a middle distal surface to the bottom distal surface; the Group III-oxide semiconductor structure comprising a first pillar extending from the intermediate first side surface to a second intermediate side surface, and a second pillar extending from a third intermediate side surface to the fourth intermediate side surface.

33. The Group III-oxide semiconductor device of claim 32, wherein the at least one deep acceptor doped region comprises a first deep acceptor doped region extending from the first side surface to a first intermediate side surface, and a second deep acceptor doped region extending from a fourth intermediate side surface to the second side surface; wherein the at least one deep acceptor doped region also comprises a third deep acceptor doped region disposed between the first deep acceptor doped region and the second deep acceptor doped region and extending from the second intermediate side surface to the third intermediate side surface, and from the middle distal surface to the top distal surface, the middle distal surface located between the bottom distal surface and the top distal surface.

34. The Group III-oxide semiconductor device of claim 28 wherein the Group III-oxide semiconductor structure extends from a first intermediate side surface to a second intermediate side surface, and has a Group III-oxide semiconductor pillar is disposed on the top distal surface of the Group III-oxide layer; a first side surface of the Group III-oxide semiconductor pillar disposed a distance away from the first intermediate side surface, a second side surface of the Group III-oxide semiconductor pillar disposed a distance away from the second intermediate side surface; wherein the at least one deep acceptor doped region comprises a first deep acceptor doped region extending from the first side surface to a first intermediate side surface, and a second deep acceptor doped region extending from a second intermediate side surface to the second side surface.

35. The Group III-oxide semiconductor device of claim 30 wherein the first Group III-oxide semiconductor structure has an indented region extending from a third intermediate side surface to a fourth intermediate side surface, the indented region extending from a middle distal surface to the bottom distal surface; the indented region producing two pillars, one pillar extending from the first side surface to the third intermediate side surface, and a second pillar extending from the fourth intermediate side surface to the first intermediate side surface.

36. The Group III-oxide semiconductor device of claim 28 wherein a deep acceptor used in doping the deep acceptor doped III-oxide substrate comprises Iron(Fe).

37. The Group III-oxide semiconductor device of claim 1, wherein the at least one deep acceptor doped region comprises a number of deep acceptor doped sub-regions.

38. The Group III-oxide semiconductor device of claim 37, wherein deep acceptor doped sub-regions, from a second sub-region to a next to last sub-region, are each disposed on a previous sub region.

39. The Group III-oxide semiconductor device of claim 38, wherein each sub-region has a doping concentration for said each sub-region.

40. The Group III-oxide semiconductor device of claim 37, wherein each sub-region, for a second sub-region to a last sub-region, has a first side surface of said each sub-region is substantially parallel to a first side surface for a first sub-region, and a second side surface of said each sub-region is substantially parallel to a first side surface for a first sub-region.

41. The Group III-oxide semiconductor device of claim 40, wherein each sub-region has a doping concentration for said each sub-region.

42. The Group III-oxide semiconductor device of claim 40, wherein each sub-region extends from a middle distal surface to the top distal surface.

43. The Group III-oxide semiconductor device of claim 42, wherein a Group III-oxide semiconductor pillar is disposed between each two subsequent sub regions.
